(19) United States
(12) Patent Application Publication
(10) Pub. No.: US 2007/0284692 A1
(43) Pub. Date: Dec. 13, 2007

(54) DEVICE ISOLATION STRUCTURE INCORPORATED IN SEMICONDUCTOR DEVICE AND METHOD OF FORMING THE SAME

(75) Inventors: Yong-Woo Lee, Gyeonggi-do (KR); Dae-Woong Kim, Daegu-gwangyeoksi (KR); Yong-Hwan Ryu, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/761,949

(22) Filed: Jun. 12, 2007

(30) Foreign Application Priority Data
Jun. 12, 2006 (KR) 2006-52603

(51) Int. Cl. H01L 29/00

(52) U.S. Cl. 257/510

(57) ABSTRACT

The structure of the present invention comprises a semiconductor substrate and a trench region formed on the semiconductor substrate. The trench region includes an extended funnel portion in the vicinity of the semiconductor substrate surface. A device isolation layer is formed at the trench region. The device isolation layer includes a void formed at a lower level than the funnel portion. The sidewalls of the hard mask pattern and the internal walls of the trench region are etched to form a funnel portion with an extended trench region at the vicinity of the semiconductor substrate surface. Accordingly, the void in the trench region does not extend above a surface of the semiconductor substrate.

### CROSS-REFERENCE TO RELATED APPLICATIONS

This U.S. non-provisional patent application claims priority under 35 U.S.C. §119 to Korean Patent Application No. 2006-52603, filed on Jun. 12, 2006, the entirety of which is hereby incorporated by reference.

### BACKGROUND

1. Technical Field

The present invention relates to a semiconductor device and method of forming the same, more specifically a device isolation structure incorporated in a semiconductor device and method of forming the same.

2. Description of the Related Art

A semiconductor device has a structure including a plurality of unit devices on a substrate. In order to electrically separate the devices, various forms of device isolation structures are formed on a substrate and the device isolation structures define active regions where the unit devices will be formed.

The device isolation structure is formed in such a way as to be suitable for scaling down of devices and/or functions of the semiconductor device. Recently, semiconductor devices have been developed to have less space between adjacent components. Accordingly, the role of device isolation structures is becoming more significant. Especially for image sensor devices, deep trench device isolation structures are adopted in order to increase the optical effect in the devices. Deep trench device isolation structures are formed in an aspect ratio higher than 10:1, and the high aspect ratio often results in the formation of a void which is not filled up entirely.

FIGS. 1 to 4 are process cross-sectional views illustrating a method of forming a conventional device isolation structure.

Referring to FIG. 1, a method of forming a device isolation structure includes forming a hard mask pattern on the semiconductor substrate 10. The hard mask pattern may be made of material that may have etch selectivity with respect to the semiconductor substrate 10. Generally hard mask patterns are made of silicon nitride. Silicon oxide may be stacked on the silicon nitride to form a deep trench structure. The structure of a conventional hard mask pattern is described below.

As shown, a silicon nitride layer 14 and a silicon oxide layer 16 may be stacked on the semiconductor substrate 10, and a photo-resist pattern 18 is formed on the silicon oxide layer 16. A buffer oxide layer 12 is further formed to relieve stresses between the semiconductor substrate 10 and the silicon nitride layer 14.

The photo-resist pattern 18 is used as an etch mask, and the silicon oxide 16, the silicon nitride 14 and the buffer oxide 12 are patterned to form a hard mask pattern. The hard mask pattern has an opening 20, and the semiconductor substrate is exposed in the opening 20 to define a region where the device isolation structure will be formed.

Referring to FIG. 2, the photo-resist pattern 18 is removed, and the semiconductor substrate exposed in the opening 20 is etched using the hard mask pattern as an etch mask. The semiconductor substrate is etched to form a trench region 22. In order to form a deep trench region, the hard mask pattern must have a sufficient selectivity and thickness with respect to the semiconductor substrate 10.

Referring to FIG. 3, an insulation layer 26 is formed on the entire surface of the substrate 10 where the trench region 22 is formed. The insulation layer 26 may be formed conformally to fill the trench region 22 completely. However, as the insulation layer is not formed perfectly conforming to the bottom structure, a void 28 is formed in the deep trench region with a high aspect ratio.

The trench region 22 and the opening of the hard mask pattern constitute an opening region. The reason that the void 28 is formed is because a thick insulation layer is formed along the curved portion of the top of the opening region, thereby closing the top of the opening region before the opening is entirely filled. The higher the aspect ratio of the opening region, the closer the void 28 moves upward toward the top of the opening region. Accordingly, the deeper the trench region and the thicker the hard mask pattern, the higher the void moves toward the top of the opening, and it is possible that the void may extend to a higher level than the top surface of the semiconductor substrate.

Referring to FIG. 4, a planarization process such as a CMP process is performed to planarize the insulation layer 26 and the silicon oxide 16, and to remove the silicon nitride 14. The buffer oxide 12 is removed and the device isolation layer 26p formed in the trench region 22 is disposed on the semiconductor substrate by cleaning and curing of the semiconductor substrate surface.

As shown, the void 28, extending to a higher level than the surface of the substrate 10, remains as a seam 28a on the device isolation layer 26p. When organic matter or conductive matter accumulates in the seam 28a during subsequent processes, it may become a contaminant or leave remainder particles causing a process defect or a semiconductor device defect.

### SUMMARY

Example embodiments of the present invention are directed to a device isolation structure incorporated in a semiconductor device and method of forming the same. In an example embodiment, the device may include a device isolation structure comprising: a semiconductor substrate; a trench region formed on the semiconductor substrate, the trench region including an extended funnel portion formed in a vicinity of a surface of the semiconductor substrate; and a device isolation layer with a void formed in the trench region. The void may be formed under the funnel portion.

In another example embodiment, the method may include forming a device isolation structure incorporated in a semiconductor device comprising: forming a hard mask pattern on a semiconductor substrate; forming a trench region on the semiconductor substrate using the hard mask pattern as an etch mask; etching the sidewalls of the hard mask pattern and the inside walls of an upper trench region to form a funnel portion in the vicinity of the semiconductor substrate surface; filling the trench region with an insulation layer to form a device isolation layer where a void is formed under the funnel portion; and planarizing the device isolation layer and removing the hard mask pattern.

The device isolation structure of the present invention does not include a void extending above the surface of the substrate, and thereby avoids semiconductor device defects associated with contaminants accumulating in the void.

### BRIEF DESCRIPTION OF THE DRAWINGS

FIGS. 1 to 4 are cross-sectional views illustrating a method of forming a conventional device isolation structure.

FIG. 5 is a cross-sectional view illustrating a device isolation structure of an example embodiment of the present invention.

FIGS. 6 to 9 are cross-sectional views illustrating a method of forming a device isolation structure of an example embodiment of the present invention.

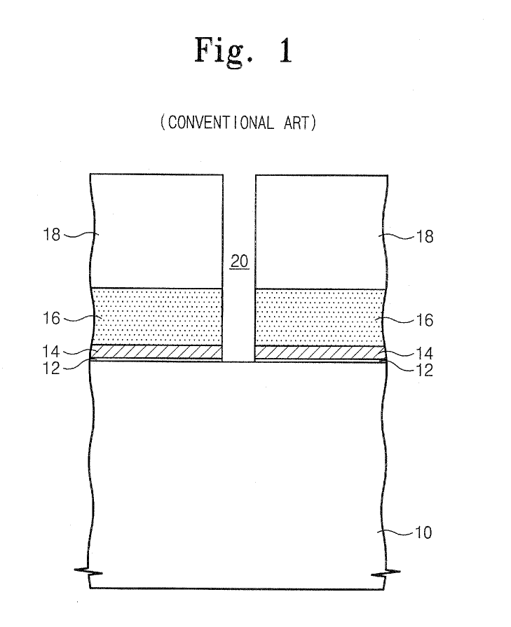

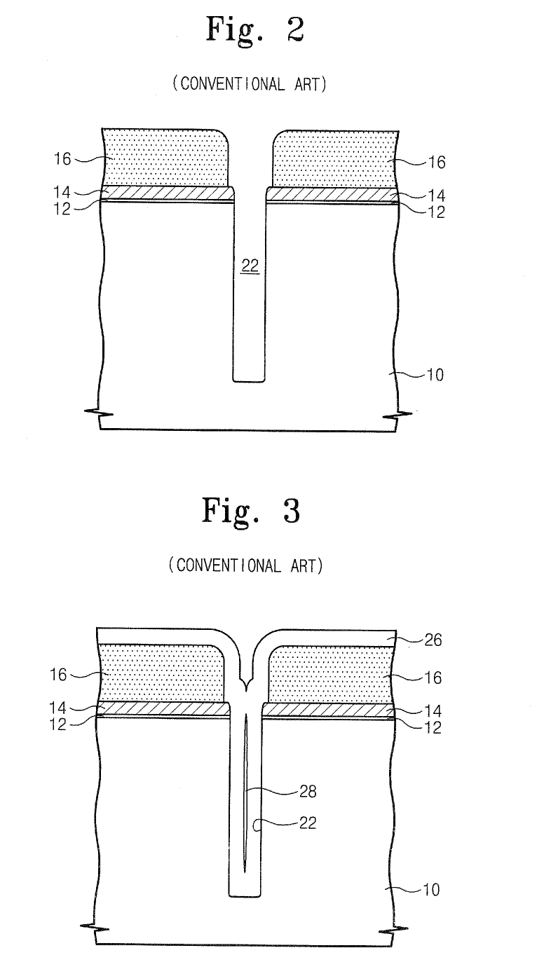

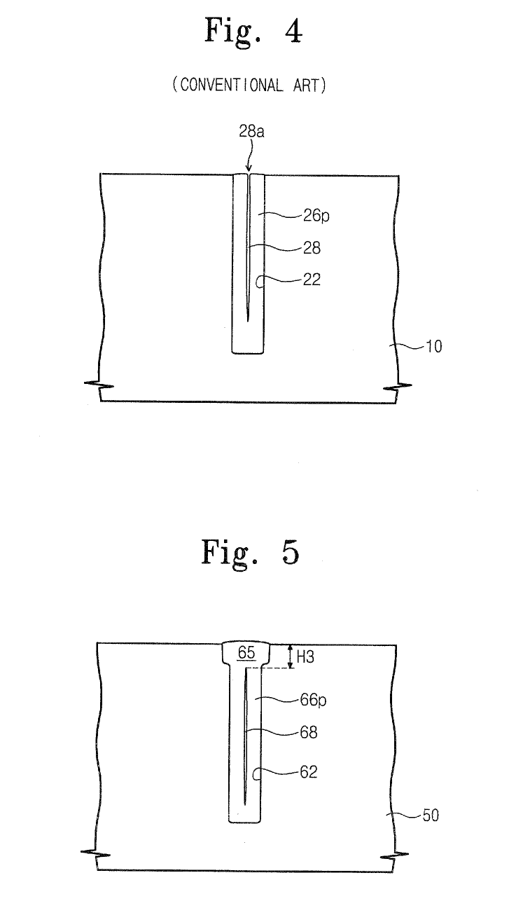

### DETAILED DESCRIPTION

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like reference numbers refer to like elements throughout.

FIG. 5 illustrates a cross-sectional view of a device isolation structure of a semiconductor device according to an example embodiment of the present invention.

Referring to FIG. 5, the device isolation structure of the present invention comprises a trench region 62 formed on the semiconductor substrate 50, and a device isolation layer 66p filling the trench region 62. The device isolation layer 66p has a void 68 formed at a lower level, at a predetermined depth H3, than the semiconductor substrate surface. The trench region 62 has an extended funnel portion 65 in the vicinity of the surface of the semiconductor substrate 50. The device isolation layer 66p fills the funnel portion 65 to have a more laterally extended portion compared to the bottom part, in the vicinity of the surface of the semiconductor substrate 50. The void 68 in the device isolation layer is formed below the funnel portion 65. Accordingly, the device isolation layer 66p does not have a seam on its surface, as in the conventional methods, but instead is planarized at the surface.

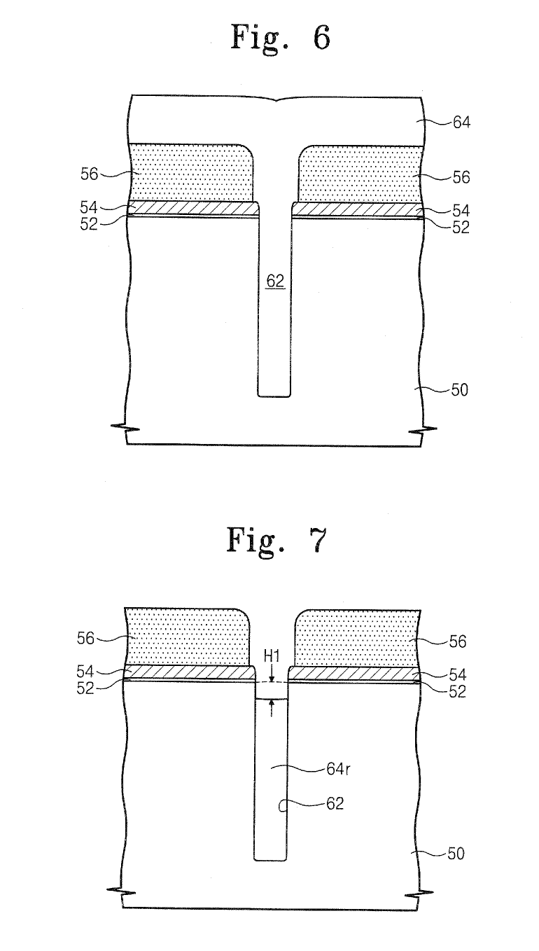

FIGS. 6 to 9 are cross-sectional views illustrating a method of forming a device isolation structure of a semiconductor device according to an example embodiment of the present invention.

Referring to FIG. 6, a hard mask pattern is formed on the semiconductor substrate 50, and the hard mask pattern is used as an etch mask to etch the semiconductor substrate 50. The hard mask pattern may be formed in the same way as a conventional structure. For example, the hard mask pattern may comprise a buffer oxide 52, a silicon nitride layer 54 and a silicon oxide layer 56.

The curved edges of the silicon nitride layer 54 and the silicon oxide layer 56 may be etched while the semiconductor substrate is etched to form a trench.

An organic layer 64, filled in the trench region 62, is disposed on substantially the entire surface of the substrate. The organic layer 64 may be selected from a substance with superb liquidity such as photo-resist or organic anti-reflective coating. For example, the organic layer 64 may be formed of various organic materials using the novolac resin or hydroxystyrene as a backbone. The organic layer 64 can fill a trench having a high aspect ratio without forming a void.

The hard mask pattern may be formed thick so that it may have sufficient etch resistance while a deep trench region is formed. Conventionally, the aspect ratio increase of the opening region due to a thick hard mask pattern caused a void to extend to a higher level than the surface of the semiconductor substrate. Also, the thickness of the hard mask pattern had to be selected with care, considering both etch resistance and void formation. However, the present invention is relatively free from considerations of void formation, when selecting the thickness of the hard mask pattern.

Referring to FIG. 7, the organic layer 64 is etched back to expose sidewalls of the hard mask on the trench region 62. The organic layer 64 is recessed a predetermined amount H1 below the surface of the semiconductor substrate 50. A portion of the semiconductor substrate 50 which defines sidewalls of the trench region 62 is exposed above the recessed organic layer 64r.

For example, the organic layer 64 may be etched back using an anisotropic dry etch. The etch selectivity of the anisotropic dry etch to silicon oxide may be higher than 1:1 or higher than 3:1. Here, an end point of the etch may be detected using the silicon oxide layer 56 as an etch stop layer, and the organic layer 64 may be further etched so that it may be recessed to a desired level.

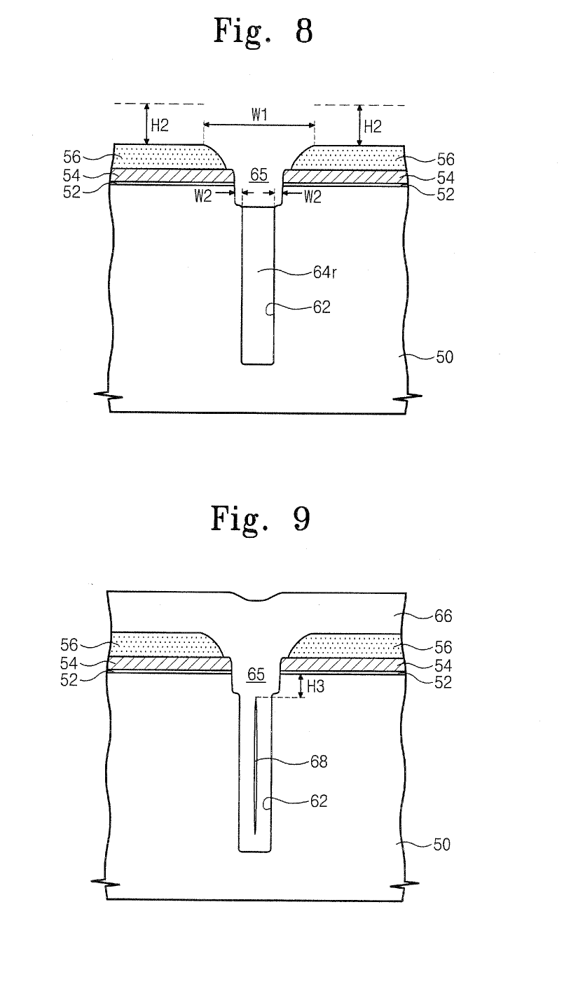

Referring to FIG. 8, at the same time as etching the sidewalls of the hard mask pattern, the sidewalls of the trench region 62 on the recessed organic layer 64r are pulled back to form a funnel portion 65 which is extended for a predetermined width W2 above the trench region 62. Here, sidewalls of the silicon oxide layer 56 and silicon nitride layer 54, which constitute the hard mask pattern, are pulled back to extend the width W1 of an opening region where the trench region 62 is exposed. This results in the width of the trench region 62 in the vicinity of the surface of the semiconductor substrate 50 being widened. The sidewalls of the hard mask pattern are slanted and the width of the hard mask is widened so that the aspect ratio of the opening region decreases. The opening region comprises the openings of the trench region 62 and the hard mask pattern.

The hard mask pattern is pulled back, and at the same time the thickness of the hard mask pattern is decreased by a predetermined amount H2. Therefore, the aspect ratio of the opening region to be filled with an insulation layer is further lowered.

During the pull-back process, the selectivity of the recessed organic layer 64r and the silicon oxide layer 56 are adjusted to control the shape and depth of the funnel portion 65. For example, a mixture of CₓH_{y}F_{z} type etch gas including CF₄ and CHF₃ with argon and/or O₂ may be used, and by adjusting the feed rate of O₂, the etch selectivity to the recessed organic layer 64r may be adjusted.

Referring to FIG. 9, the recessed organic layer 64r in the trench region 62 is removed to expose the semiconductor substrate 50 defining the inner walls and bottom surface of the trench region 62. Then an insulation layer 66 filling the trench region 62 is formed conformally. As shown, the sidewalls of the hard mask pattern on the trench region 62 are slanted. The trench region in the vicinity of the surface of the semiconductor substrate 50 has a wide structure and has an extended funnel portion 65. Consequently, the point in time when the insulation layer 66 is closed at the funnel portion 65 is delayed, thereby resulting in the quantity of the insulation layer 66 filled in the trench region 62 being increased. As a result, the void 68 is formed at a lower level, by a predetermined amount H3, than the surface of the semiconductor substrate 50. As the width of the trench region 62 in the vicinity of the surface of the semiconductor substrate 50 is relatively larger than its bottom part, the void 68 may be formed at a lower level than the funnel portion 65.

Although not shown, the insulation layer 66 and the silicon oxide layer 56 are planarized to expose the silicon nitride layer 54. Then the silicon nitride layer 54 is removed and a successive process is performed to form a trench device isolation structure on the semiconductor substrate. The insulation layer 66 may be made of silicon oxide. Accordingly, it may be planarized with the silicon oxide layer 56 constituting the hard mask layer. A CMP process may be used in the planarizing of the silicon oxide.

Before filling the trench region 62 with the silicon oxide, a step of forming a trench oxide curing damage from etch on the sidewalls of the trench region 62 and a step of forming a conformal silicon nitride liner on the entire surface of the substrate 50 may be added.

According to the present invention, a trench region having a funnel portion in the vicinity of a semiconductor substrate surface may be formed to increase the width of the top of the trench region.

In addition, the width of the hard mask pattern is increased and may be formed so that the sidewalls are slanted, and the thickness of the hard mask pattern may further be decreased after forming the trench region. Accordingly, the top of the opening region filled with an insulation layer may have a small slope and have a large width.

Finally, the present invention may have a void formed at a lower level than the surface of the semiconductor substrate and further have a void formed at a lower level than a funnel portion of the trench region to prevent a seam from being formed after a device isolation layer planarization process. Therefore, contamination being caught in between the device isolation layer may be prevented, thereby eliminating process defects and semiconductor device defects associated with the device isolation layer.

Although the present invention has been described in connection with the embodiment of the present invention illustrated in the accompanying drawings, it is not limited thereto. It will be apparent to those skilled in the art that various substitutions, modifications and changes may be made thereto without departing from the scope and spirit of the invention as defined by the following claims.

What is claimed is:

1. A device isolation structure incorporated in a semiconductor device, comprising:
a semiconductor substrate;
a trench region disposed on the semiconductor substrate, the trench region including an extended funnel portion disposed in a vicinity of a surface of the semiconductor substrate; and
a device isolation layer including a void disposed in the trench region, wherein the void is disposed under the funnel portion.

2. The structure of claim 1, wherein the funnel portion of the trench region is filled by the device isolation layer.

3. The structure of claim 2, wherein the device isolation layer filled in the funnel portion has a larger width than a bottom portion thereof.

4. The structure of claim 1, wherein the void is disposed a pre-determined depth below the surface of the semiconductor substrate.

5. A method of forming a device isolation structure incorporated in a semiconductor device, comprising:
forming a hard mask pattern on a semiconductor substrate;
forming a trench region on the semiconductor substrate using the hard mask pattern as an etch mask;
etching sidewalls of the hard mask pattern and internal walls of the trench region to form a funnel portion in the vicinity of the semiconductor substrate surface;
filling the trench region with an insulation layer to form a device isolation layer, wherein a void is formed under the funnel portion; and
planarizing the device isolation layer and removing the hard mask pattern.

6. The method of claim 5, wherein forming the funnel portion comprises:
forming an organic layer in the trench region, the organic layer recessed below a surface of the semiconductor substrate to expose a portion of the top surface and sidewalls of the hard mask pattern and a portion of the trench region; and
pulling back the sidewalls of the hard mask pattern on the organic layer and the internal wall of the exposed trench region.

7. The method of claim 6, wherein forming the organic layer comprises:
forming an organic layer filling the trench region and covering the hard mask pattern; and
etching back the organic layer and recessing the organic layer to a lower level than the semiconductor substrate surface, thereby exposing the portion of the top surface and sidewalls of the hard mask pattern and the portion of the internal wall of the trench region.

8. The method of claim 7, wherein recessing the organic layer comprises:
using the hard mask pattern as an etch stopping layer and etching the organic layer to expose the top surface of the hard mask pattern; and
further recessing the organic layer to expose the portion of the sidewalls of the hard mask pattern and the portion of the internal wall of the trench region.

9. The method of claim 6, further comprising, during the pulling back of the internal wall of the exposed trench region, decreasing the thickness of the hard mask pattern.

10. The method of claim 6, wherein forming the hard mask pattern comprises:
stacking a buffer oxide layer, a silicon nitride layer and a mask oxide layer on the semiconductor substrate;
forming a photo-resist pattern on the mask oxide layer;
sequentially patterning the mask oxide layer, the silicon nitride layer, and the buffer oxide layer using the photo-resist pattern as an etch mask to expose a portion of the semiconductor substrate; and
removing the photo-resist pattern.

11. The method of claim 10, wherein, the silicon nitride layer has a smaller thickness than the mask oxide layer.

12. The method of claim 10, wherein the pulling back of the sidewalls of the hard mask pattern comprises, pulling back the silicon nitride layer and the mask oxide layer, and wherein the sidewalls of the mask oxide layer have a slope.

13. A device isolation structure, comprising:
a substrate;
a hard mask pattern on the substrate;
a trench disposed in the substrate, the trench comprising a lower region and a funnel region, wherein the funnel region is wider than the lower region; and
an insulation layer disposed in the funnel region and the lower region of the trench, the insulation layer comprising a void.

14. The structure of claim 13, wherein the hard mask pattern comprises:
a buffer oxide layer on the substrate;
a silicon nitride layer on the buffer oxide layer; and
a silicon oxide layer on the silicon nitride layer.

15. The structure of claim 14, wherein the hard mask layer comprises an opening above the trench and wherein a portion of the opening defined by the silicon oxide layer is wider than the funnel region.

16. The structure of claim 15, wherein the portion of the opening defined by the silicon oxide layer has sloped sidewalls.

17. The structure of claim 13, further comprising a recessed organic layer in the lower region of the trench.

18. The structure of claim 13, wherein the void is disposed below the funnel region.
